(19) United States
(12) Patent Application Publication
(10) Pub. No.: US 2002/0126770 A1
(43) Pub. Date: Sep. 12, 2002

(54) Method and system for acquiring narrowband channel information over a wideband channel receiver

(76) Inventors: Behrouz Pourseyed, Vancouver (CA); Nicholas P. Alfano, Vancouver (CA)

Correspondence Address: Robert E. Krebs, Esq., BURNS, DOANE, SWECKER & MATHIS, L.L.P., P.O. Box 1404, Alexandria, VA, 22313-1404, US

(21) Appl. No.: 09/802,544

(22) Filed: Mar. 9, 2001

(51) Int. Cl. H04L 27/22; H03D 3/24; H03D 3/00

(52) U.S. Cl. 375/324; 375/327; 329/304; 329/307

(57) ABSTRACT

A system for demodulating narrowband signals from a received signal is disclosed. The system includes a downconverter that is operative to downconvert the received signal. Furthermore, the system includes a baseband processor that is configured to decode the narrowband signal from the received signal, as well as decode wideband signals. In this respect, the system is operative to demodulate both narrowband and wideband signals without the use of separate demodulation paths.

### BACKGROUND OF THE INVENTION

1. Field of the Invention

The present invention generally relates to a system and method of receiving narrowband channel information and more particularly to a system and method whereby a wideband receiver is utilized to receive the narrowband channel information.

2. Status of the Prior Art

The primary devices of a wireless communications system such as a cellular radio network consist of a fixed network infrastructure and a mobile terminal. The fixed network infrastructure normally consists of base stations, mobile switching centers, network management equipment, and other equipment used to support connectivity to other fixed or mobile communication devices or to provide other specific services. The mobile terminal or mobile station is an untethered device having its own power source supporting a radio transmitter and receiver. The mobile station and the base station communicate over predefined radio frequencies obeying a set of protocols used to establish a connection and transfer information via that connection. Within the set of protocols executed between the mobile station and the base station, there exist two generic types of information that can be categorized as control (signaling) information and traffic information.

Control information is normally, but not exclusively, transmitted from the base station to the mobile station. The mobile station upon receiving and interpreting the control information may derive the method for obtaining the traffic information. For example, the control information may be the radio frequency and coding scheme used to transfer the traffic information. The traffic information may be human audible voice, data, images or any combination of multi-media transmissions that could be usable for conveying information.

The definition of a radio frequency used in cellular radio networks includes a frequency bandwidth usually defined in terms of Hz. In the case of Time Division Multiple Access (TDMA) protocols defined by the TIA/EIA-136 specifications, the bandwidth is 30 kHz between usable radio frequencies. In the case of the Global System for Mobile Communications (GSM) the ETSI specifications define a radio frequency bandwidth of 200 kHz.

When a mobile station moves between areas of different coverage (i.e., different cells), it may loose a preexisting connection with a base station because the mobile station has moved out of the transmission range of the base station. Similarly, a mobile station which goes through a power-on, power-off, power-on cycle would loose a preexisting connection. To establish or re-establish a connection between a mobile station and a base station, the mobile station executes a protocol to monitor a predefined set of radio frequencies at a predefined bandwidth to locate the control information necessary to locate traffic information. Typically, the control information is continuously transmitted by the base station to accommodate mobile stations which may arrive at anytime within the coverage area of the base station.

The receipt of the control information may or may not require the mobile station to transmit information about itself to the fixed network infrastructure. The procedure to establish a 2-way connection between a mobile station and a base station normally requires the mobile station to announce its presence to the fixed network infrastructure, but whether this occurs as part of the control information or whether it is transmitted over the traffic information radio frequencies is a function of the defined protocol for that particular cellular network technology in use.

Typically, the mobile station combining TDMA and GSM technologies of the prior art demodulates both the control information and the traffic information using dual receivers. The first receiver has a wideband demodulation path for demodulating the GSM information, whereas the second path has a narrowband demodulation path for demodulating the TDMA information. By utilizing dual receivers, it is possible for the mobile station to demodulate both the control information and the traffic information.

However, dual receivers add increased cost and complexity to the mobile station. A first receiver is utilized for the demodulation of traffic information, while a second receiver is utilized for the demodulation of control information. Therefore, the overall cost and complexity of the system is increased due to the dual receivers.

The present invention addresses the above-mentioned deficiencies in the prior art mobile station design by providing a receiver that is operable to demodulate both the wideband traffic information as well as the narrowband control information. In this respect, the present invention provides a system and method of using a single receiver with a wideband channel to acquire narrowband channel information. As will be recognized by those of ordinary skill in the art, the present invention provides a system and method which reduces the overall complexity of the prior art mobile stations by providing a simple receiver which is capable of receiving both control and traffic information.

### SUMMARY OF THE INVENTION

In accordance with the present invention, there is provided a system for demodulating narrowband signals from a received signal. The system comprises a downconverter and a baseband processor in electrical communication with the downconverter. In this respect, the downconverter is operative to downconvert the received signal and the baseband processor is operative to decode the narrowband signal from the received signal. Additionally, the baseband processor is operative to decode wideband signals. Typically, the wideband signals will have a bandwidth of about 200 kHz and the narrowband signals will have a bandwidth of about 30 kHz.

The downconverter will comprise at least one analog to digital converter that is operative to convert the received analog signal into a received digital signal for decoding by the baseband processor. Furthermore, the downconverter will have a quadrature demodulator operative to demodulate the received signal prior to converting the signal to a digital signal. The quadrature demodulator is operative to generate two signals in quadrature phase which are fed to respective digital to analog converters. Prior to demodulation, the received signal is mixed by a mixer with a radio frequency oscillation signal generated by a radio frequency phase lock loop. The downconverter will further include an amplifier that is operative to increase the gain of the received signal and control the system noise figure prior to mixing.

In accordance with the present invention, there is provided a method of demodulating narrowband signals from a received signal with a downconverter and a baseband processor. The method comprises the steps of downconverting the received signal with the downconverter and then decoding the narrowband signal from the received signal with the baseband processor. Additionally, the method further includes decoding a wideband signal from the received signal with the baseband processor. In this respect, narrowband signals having a bandwidth of about 30 kHz and wideband signals having a bandwidth of about 200 kHz are decoded with the baseband processor.

In accordance with the present invention, there is provided a wireless receiver operative to receive at least one 200 kHz (wideband) channel. The receiver comprises an antenna that is operative to detect a received signal. A switch filter is in electrical communication with the antenna. The switch filter is operative to switch between the received signal and a transmitted signal. The receiver further includes an amplifier in electrical communication with the switch filter. The amplifier is operative to increase the gain of the received signal and control system's noise figure. A mixer is in electrical communication with the amplifier. The mixer is operative to mix the received signal with a radio frequency oscillation signal generated by a radio frequency phase lock loop. The receiver further includes a demodulator in electrical communication with the mixer. The demodulator is operative to demodulate the received signal with an intermediate frequency oscillation signal generated by an intermediate frequency phase lock loop. An analog to digital converter is in electrical communication with the demodulator and is operative to convert the received signal to a digital received signal. In order to receive the narrowband channel, the receiver further includes a baseband processor in electrical communication with the analog to digital converter. The baseband processor is operative to decode the wideband channel information, as well as narrowband channel information.

### BRIEF DESCRIPTION OF THE DRAWINGS

These, as well as other features of the present invention, will become more apparent upon reference to the drawings wherein:

FIG. 1 is a block diagram of a receiver for a prior art wideband-narrowband receiver system;

FIG. 2 is a generalized block diagram of a wideband receiver with baseband implementation of a narrowband channel constructed in accordance with the present invention; and

FIG. 3 is a detailed block diagram of the receiver shown in FIG. 2.

### DETAILED DESCRIPTION OF THE PREFERRED EMBODIMENT

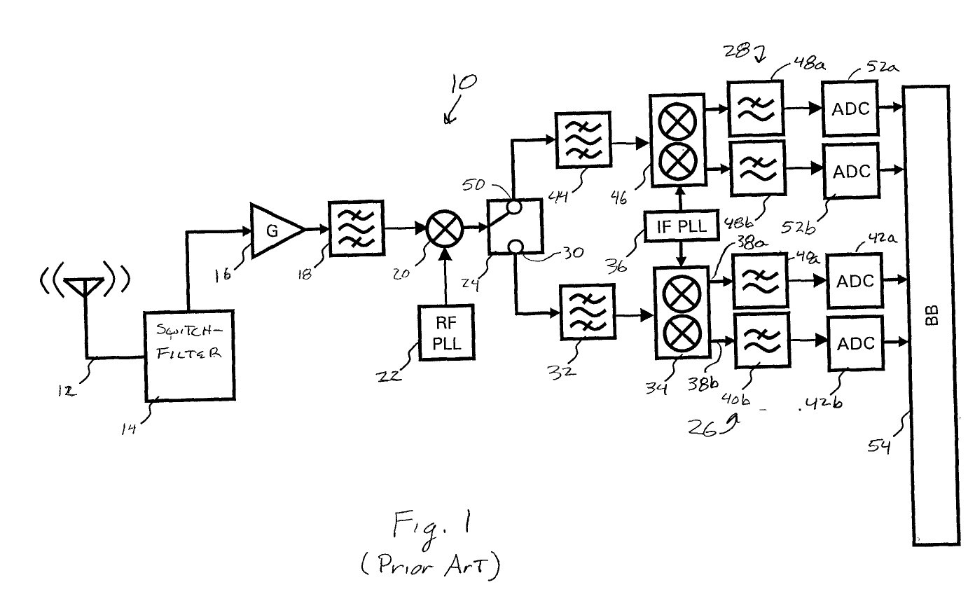

Referring now to the drawings wherein the showings are for purposes of illustrating a preferred embodiment of the present invention only, and not for purposes of limiting the same, FIG. 1 is a block level diagram showing a conventional wideband-narrowband receiver system 10 for a mobile station of the wireless communications network. In the prior art receiver system 10, an antenna 12 receives both control information and traffic information. As previously mentioned above, the control information is typically on a narrower band than the traffic information. Specifically, the control information has a bandwidth of approximately 30 kHz, whereas the traffic information has a bandwidth of approximately 200 kHz. The antenna 12 is connected to a branching (switch-filter) device 14 which is operative to switch the antenna 12 between receiving functions and transmitting functions (not shown). The output of the branching device 14 is connected to a low noise amplifier 16 which increases the gain of the incoming signal from the antenna 12. The output of the amplifier 16 is connected to an image rejection filter 18 which prefilters the received signal. The output of the image rejection filter 18 is fed into a down converter mixer 20. The output of a radio frequency phase locked loop (RF PLL) 22 is additionally fed into the down converter mixer 20 which is operable to down convert the signal from the antenna 12.

The output of the down converter mixer 20 is fed to a radio frequency switch 24 that is operable to switch between a wideband receiver path 26 and a narrowband receiver path 28. The wideband path 26 is operative to demodulate the wideband traffic signals whereas the narrowband path 28 is operative to demodulate the control signals. As previously mentioned, it is contemplated that the wideband traffic signals have a bandwidth of about 200 kHz and the narrowband control signals have a bandwidth of about 30 kHz.

Referring to FIG. 1, a wideband output 30 of the RF switch 24 is fed into a wideband intermediate frequency filter 32 for filtering the signal to the correct wideband frequencies. The output of the wideband intermediate frequency filter 32 is fed into a wideband quadrature demodulator 34 which is operative to demodulate the wideband traffic information. Specifically, an output of an intermediate frequency phase lock loop (IF PLL) 36 is used by the wideband quadrature demodulator 34 to demodulate the traffic information. The wideband quadrature demodulator 34 has a first 38a and second 38b output which are in quadrature phase with one another. Each of the first and second outputs 38a and 38b from the wideband quadrature demodulator 34 are fed to an input of a respective wideband anti-aliasing filter 40a and 40b that outputs the filtered signals (in quadrature) to respective analog to digital converters 42a and 42b. The outputs of the analog to digital converters 42a and 42b are fed to baseband processor 54 which decodes the traffic information.

In order to demodulate the narrowband traffic signals, the narrowband path 28 of the prior art receiver system 10 is similar to the wideband path 26. Specifically, the narrowband path 28 includes a narrowband intermediate frequency filter 44 and a narrowband quadrature demodulator 46 operative to demodulate the narrowband signals detected by the antenna 12 and fed from narrowband output 50 of the RF switch 24. After demodulation, the signals in quadrature phase from the narrowband demodulator 46 are fed into respective anti-aliasing filters 48a and 48b. The respective outputs of the anti-aliasing filters 48a and 48b are fed into respective analog to digital converters 52a and 52b which present digital control signals to the baseband processor 54 for decoding.

As seen by the prior art wideband-narrowband receiver system 10, two demodulation paths (i.e., wideband path 26 and narrowband path 28) are used to demodulate the signals detected by the antenna 12. In order to demodulate traffic information, the RF switch 24 will direct the signals from the antenna 12 to the wideband path 26. However, in order to demodulate control information, the RF switch 24 will direct the signals from the antenna 12 to the narrowband path 28. As can be seen in FIG. 1, both the narrowband path 28 and the wideband path 26 utilize similar components. In this sense, each path 26, 28 are mirror images of one another with duplicate components. Accordingly, the prior art wideband-narrowband receiver system 10 comprises a large component count thereby increasing the size and cost of the receiver.

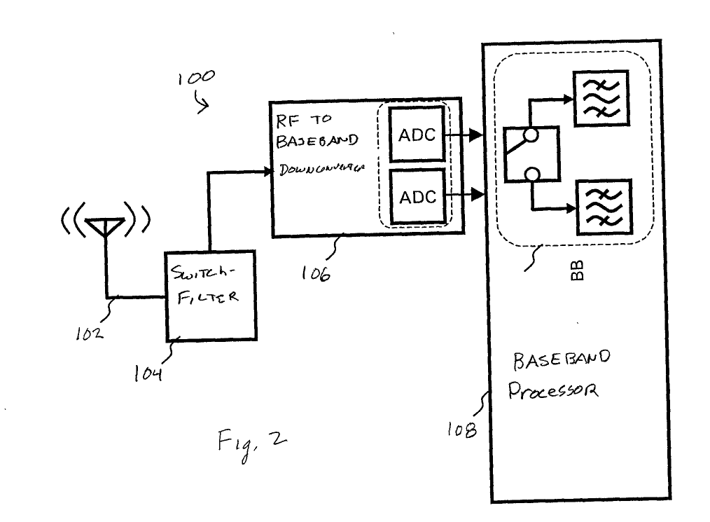

Referring now to FIG. 2, a generalized block diagram of a receiver system 100 constructed in accordance with the present invention is shown. The receiver system 100 is a wireless wideband receiver with baseband implementation of the narrowband channel. In this respect, the receiver 100 is operative to receive and demodulate both narrowband control information and wideband traffic information without the need for separate demodulation paths, as will be explained below.

The receiver 100 constructed in accordance with the present invention has an antenna 102 to transmit and receive signals to and from a mobile station. The output of the antenna 102 is fed to a branching device 104 that allows the antenna 102 to both transmit and receive signals. In this respect, the branching device 104 is a RF switch filter operative to connect the antenna 102 to the receiver system 100 for the reception of signals and connect the antenna 102 to a transmitter (not shown) for the transmission of signals. The output of the branching device 104 is fed to a radio frequency to baseband down converter 106 which is operative to downconvert the signal detected by the antenna 12 to a baseband signal. The down-converter 106 is a very low intermediate frequency down converter with an analog to digital converter having band pass sampling. The down-converter 106 produces two digital signals in quadrature phase with one another.

The outputs of the downconverter 106 are fed to a baseband processor 108 which is operative to decode the signals from the antenna 102. Specifically, the processor 108 is a digital signal processor capable to demodulate both the narrowband control information and the wideband traffic information from the signal detected by the antenna 102. The processor 108 effectively filters the signal received by the antenna 102 for narrowband control information and wideband traffic information. The effective noise floor at the baseband will be increased by capturing the narrower band 30 kHz control information. However, the sensitivity can be improved and is equal to the processing gain that is achieved through the narrowband filtering of the digitized signal at the digital signal processing level. Accordingly, the processor 108 is capable of filtering the quadrature signals generated by the downconverter 106 in order to recover the narrowband control information.

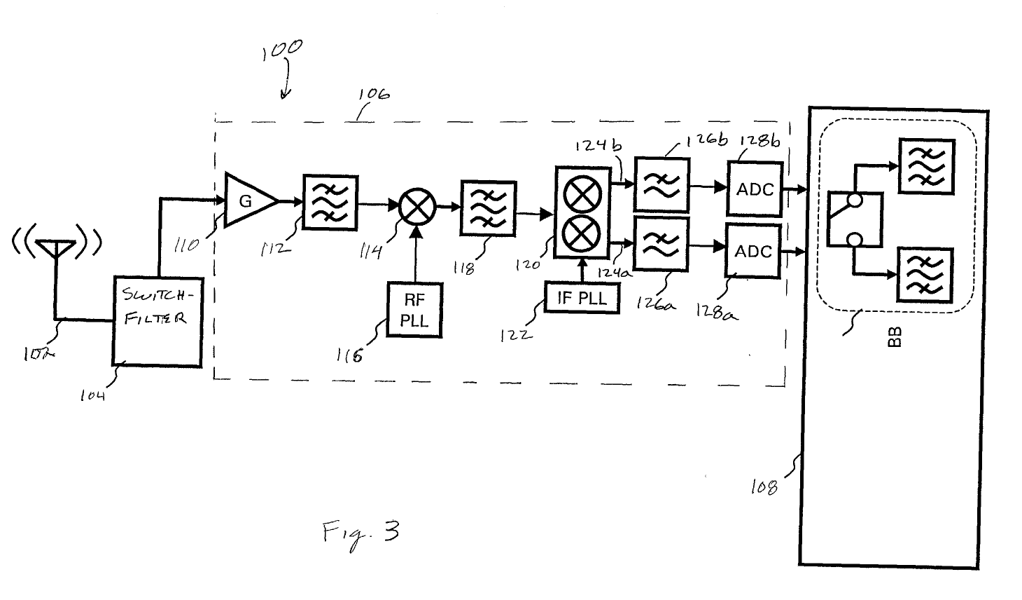

Referring to FIG. 3, a detailed block diagram of the receiver system 100 is illustrated wherein the components of the downconverter 106 are shown. The receiver system 100 has a low noise amplifier 110 which increases the gain of the signal detected by the antenna 102. The output of the low noise amplifier 110 is fed into an image rejection filter 112 for prefiltering. Next, the output of the image rejection filter 112 is fed into a down-converter mixer 114 which mixes the received signal with a local oscillator signal from a radio frequency phase lock loop 116 to generate an intermediate frequency signal at an output thereof.

The output of the down-converter mixer 114 is fed to an intermediate frequency (IF) filter 118. The output of the IF filter 118 is fed to a quadrature demodulator 120 which uses the signal from an intermediate frequency phase lock loop (IF PLL) 122 to demodulate the signal into two signals having quadrature phase. Specifically, the quadrature demodulator 120 has a first output 124a and a second output 124b which present the demodulated signal with a quadrature phase shift. Each of the outputs 124a and 124b are fed to a respective anti-aliasing filter 126a and 126b, as seen in FIG. 3. The output of each anti-aliasing filter 126a and 126b is fed to a respective analog to digital converter 128a and 128b. Each of the analog to digital converters 128a and 128b are operative to convert the received analog signal into a digital representation. The digital representation of the signal is then fed into the baseband processor 32 for decoding, as previously described above. The baseband processor 32 will capture the narrowband signal during decoding in order to determine the control information.

Additional modifications and improvements of the present invention may also be apparent to those of ordinary skill in the art. Thus, the particular combination of parts described and illustrated herein is intended to represent only certain embodiments of the present invention, and is not intended to serve as limitations of alternative devices within the spirit and scope of the invention.

1. A system for demodulating narrowband signals from a received signal, the system comprising:
a downconverter operative to downconvert the received signal; and
a baseband processor in electrical communication with the downconverter, the baseband processor being operative to decode the narrowband signal from the received signal.

2. The system of claim 1 wherein the downconverter comprises at least one analog to digital converter operative to convert the received signal to a digital signal.

3. The system of claim 2 wherein the downconverter comprises at least one demodulator operative to downconvert the received signal.

4. The system of claim 3 wherein the demodulator is a quadrature demodulator operative to demodulate the received signal into two signals shifted in phase.

5. The system of claim 4 wherein the downconverter comprises a mixer operative to mix the received signal prior to demodulation.

6. The system of claim 5 wherein the downconverter further comprises an amplifier operative to increase the gain of the received signal prior to demodulation.

7. The system of claim 1 further comprising an antenna in electrical communication with the downconverter and operative to detect the received signal.

8. The system of claim 1 wherein the baseband processor is configured to filter the received signal into a wideband channel and a narrowband channel.

9. The system of claim 1 wherein the baseband processor is operative to decode a narrowband signal having a bandwidth of about 30 kHz.

10. The system of claim 1 wherein the baseband processor is operative to decode wideband signals as well as narrowband signals.

11. The system of claim 10 wherein the narrowband signals have a bandwidth of about 30 kHz and the wideband signals have a bandwidth of about 200 kHz.

12. A method of demodulating narrowband signals from a received signal with a downconverter and a baseband processor, the method comprising the steps of:
a) downconverting the received signal with the downconverter; and
b) decoding the narrowband signal from the received signal with the baseband processor.

13. The method of claim 12 wherein step (b) further comprises decoding a wideband signal from the received signal with the baseband processor.

14. The method of claim 13 wherein step (b) comprises decoding narrowband signals having a bandwidth of about 30 kHz and wideband signals having a bandwidth of about 200 kHz.

15. The method of claim 12 wherein step (a) comprises converting the received signal to a digital signal with an analog to digital converter.

16. The method of claim 15 wherein step (a) comprises demodulating the received signal with a quadrature demodulator prior to converting the signal to a digital signal.

17. The method of claim 16 wherein step (a) comprises mixing the received signal prior to demodulation with the quadrature demodulator.

18. The method of claim 17 wherein step (a) comprises amplifying the received signal prior to mixing.

19. The method of claim 18 wherein step (a) comprises detecting the signal prior to amplification.

20. A wireless wideband receiver operative to receive at least one 200 kHz (wideband) channel, the receiver comprising:
an antenna operative to detect a received signal;
a switch filter in electrical communication with the antenna, the switch filter being operative to switch between the received signal and a transmitted signal;
an amplifier in electrical communication with the switch filter, the amplifier being operative to increase the gain of the received signal;
a mixer in electrical communication with the amplifier, the mixer being operative to mix the received signal with a radio frequency oscillation signal;
a demodulator in electrical communication with the mixer, the demodulator being operative to demodulate the received signal with an intermediate frequency oscillation signal;
an analog to digital converter in electrical communication with the demodulator, the analog to digital converter being operative to convert the received signal to a digital signal; and
a baseband processor in electrical communication with the analog to digital converter, the baseband processor being configured to decode the narrowband channel from the received signal.

21. The receiver of claim 20 wherein the baseband processor is further configured to decode a wideband channel.

22. The receiver of claim 21 further comprising a radio frequency phase lock loop in electrical communication with the mixer, the radio frequency phase lock loop being operative to generate the radio frequency oscillation signal.

23. The receiver of claim 22 further comprising an intermediate frequency phase lock loop in electrical communication with the demodulator, the intermediate frequency phase lock loop being operative to generate the intermediate frequency oscillation signal.

24. The receiver of claim 23 wherein the demodulator is a quadrature demodulator operative to demodulate the received signal into two demodulated signals having quadrature phase.

25. The receiver of claim 24 wherein the analog to digital converter comprises two analog to digital converters operative to convert the two received signals to digital signals.

26. The receiver of claim 25 wherein the wideband channel has a bandwidth of about 200 kHz and the narrowband channel has a bandwidth of about 30 kHz.

27. A system for receiving narrowband signals from a received signal comprising:
means for demodulating the received signal;
means for converting the received signal to a digital received signal; and
means for decoding the narrowband signal from the digital received signal.

28. The system of claim 27 wherein the means for decoding the narrowband signal is configured to additionally decode wideband signals.

29. The system of claim 28 wherein the means for decoding the narrowband and wideband signals is a digital baseband processor.

30. The system of claim 29 wherein the means for demodulating the received signal is a demodulator.

31. The system of claim 30 wherein the demodulator is a quadrature demodulator.

32. The system of claim 31 wherein the means for converting the received signal to a digital received signal is an analog to digital converter.

33. The system of claim 32 wherein the narrowband signals have a bandwidth of about 30 kHz and the wideband signals have a bandwidth of about 200 kHz.
